(19) United States
(12) Patent Application Publication
(10) Pub. No.: US 2025/0277298 A1
(43) Pub. Date: Sep. 4, 2025

(54) MASK DEVICE

(71) Applicant: KunShan Go-Visionox Opto-Electronics Co., Ltd., Kunshan (CN)

(72) Inventors: Xue CUI, Kunshan (CN); Wenxing LI, Kunshan (CN)

(73) Assignee: KunShan Go-Visionox Opto-Electronics Co., Ltd., Kunshan (CN)

(21) Appl. No.: 19/211,253

(22) Filed: May 18, 2025

Related U.S. Application Data
(63) Continuation of application No. PCT/CN2023/098850, filed on Jun. 7, 2023.

(30) Foreign Application Priority Data
Dec. 1, 2022 (CN) 202211541023.4

(51) Int. Cl. C23C 14/04

(52) U.S. Cl. CPC C23C 14/042

(57) ABSTRACT

The present application relates to a mask device, including: a first mask having a plurality of evaporation regions and separation regions located between the plurality of evaporation regions, evaporation openings being formed in each of the evaporation regions; and a second mask arranged on one side of the first mask in a thickness direction thereof, the second mask having a shielding portion and a plurality of shaping openings formed in the shielding portion, each of the shaping openings being arranged corresponding to one of the evaporation regions; where an orthographic projection of the shielding portion covers at least some of the evaporation openings in the thickness direction. The mask device provided in the embodiments of the present application can meet the requirements of evaporation of a special-shaped region and can also alleviate the problem of serious impact of evaporation color spots on the effect of display.

### CROSS-REFERENCE TO RELATED APPLICATIONS

The present application is a continuation of International Application No. PCT/CN2023/098850 filed on Jun. 7, 2023, which claims priority to Chinese Patent Application No. 202211541023.4, entitled “MASK DEVICE” and filed with the China National Intellectual Property Administration on Dec. 1, 2022. All of the aforementioned patent applications are hereby incorporated by reference in their entireties.

### FIELD

The present application relates to the field of display, and in particular to a mask device.

### BACKGROUND ART

Organic light-emitting diodes (OLEDs) have gradually become the mainstream in the display field thanks to their characteristics such as low power consumption, high color saturation and wide angle of view.

For OLED display panels, a mask is typically used to deposit a coating film material by evaporation. With the continuous development of display technology, the requirements for the shapes of display panels vary, there are generally some special-shaped regions, and if the requirements for the shapes of the special-shaped regions are met by changing the distribution or shape of evaporation openings in a mask device, the problem of influences on the effect of display due to the presence of serious evaporation color spots occurs.

### SUMMARY

Embodiments of the present application provides a mask device, which can meet the requirements of evaporation of a special-shaped region and can also alleviate the problem of serious impact of evaporation color spots on the effect of display.

In an aspect, an embodiment of the present application provides a mask device, including: a first mask having a plurality of evaporation regions and separation regions located between the plurality of evaporation regions, evaporation openings being formed in each of the evaporation regions; and a second mask arranged on one side of the first mask in a thickness direction thereof, the second mask having a shielding portion and a plurality of shaping openings formed in the shielding portion, each of the shaping openings being arranged corresponding to one of the evaporation regions; where an orthographic projection of the shielding portion covers at least some of the evaporation openings in the thickness direction.

The mask device provided in the embodiments of the present application includes a first mask and a second mask, where the first mask has a plurality of evaporation regions and separation regions between the plurality of evaporation regions, and evaporation openings are formed in each of the evaporation regions and configured to form evaporation patterns of corresponding shapes. The second mask is arranged on one side of the first mask in a thickness direction thereof, and the second mask has a shielding portion and a plurality of shaping openings formed in the shielding portion. Each shaping opening is arranged corresponding to one of the evaporation regions, and the orthographic projection of the shielding portion covers at least part of the evaporation openings in the thickness direction, such that when a predetermined material is evaporated in the evaporation openings of the evaporation regions, corresponding areas of the covered evaporation openings can be shielded by the shielding portion. By setting the shapes of the shaping openings to match the shapes of special-shaped regions, the requirements of evaporation can be met without changing the distribution or shapes of the evaporation openings at the positions corresponding to the special-shaped regions, such that the problem of the serious impact of evaporation color spots on the effect of display can be alleviated.

### BRIEF DESCRIPTION OF THE DRAWINGS

Embodiments of the present application will be described below with reference to the accompanying drawings.

FIG. 1 is a structural schematic diagram of a mask device according to an embodiment of the present application;

FIG. 2 is a structural schematic diagram of a first mask according to an embodiment of the present application;

FIG. 3 is a structural schematic diagram of a second mask according to an embodiment of the present application;

FIG. 4 is a partial structural schematic diagram of positions where shaping openings are enclosed in a second mask according to an embodiment of the present application;

FIG. 5 is a sectional view taken along line A-A in FIG. 4;

FIG. 6 is a partial structural schematic diagram of positions where shaping openings are enclosed in a second mask according to another embodiment of the present application;

FIG. 7 is a sectional view taken along line B-B in FIG. 6;

FIG. 8 is a chart of simulation analysis of a mask device according to an embodiment of the present application;

FIG. 9 is a structural schematic diagram of a first mask according to another embodiment of the present application; and

FIG. 10 is a structural schematic diagram of a second mask according to another embodiment of the present application.

In the figures, like parts are denoted by the same reference numerals. The drawings are not drawn to actual scale.

### DETAILED DESCRIPTION OF EMBODIMENTS

The features and exemplary embodiments of the present application in various aspects will be described in detail below. In the following detailed description, many specific details are set forth to provide full understanding of the present application. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures or characteristics described below may be combined, in any suitable manner, in one or more embodiments.

The orientation terms in the following description all indicate directions shown in the accompanying drawings, and do not limit a specific structure of a mask device in the present application. In the description of the present application, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection.

With the continuous development of display technology, the requirements for display effects of display panels have been constantly increased. Organic light-emitting diodes (OLEDs) have gradually become the mainstream in the display field thanks to their characteristics such as low power consumption, high color saturation and wide angle of view. For OLED display panels, a mask is typically used to deposit a coating film material by evaporation. With the continuous development of display technology, the requirements for the shapes of display panels vary, there are generally some special-shaped regions, and if the requirements for the shapes of the special-shaped regions are met by changing the distribution or shape of evaporation openings in a mask device, the mask device is prone to wrinkling so that when the mask device is used for forming a display panel, the formed display device suffers from the problem of serious evaporation color spots which affect the effect of display.

On this basis, the embodiments of the present application provide a novel mask device, which can meet the requirements of evaporation of a special-shaped region and can also alleviate the problem of serious impact of evaporation color spots on the effect of display.

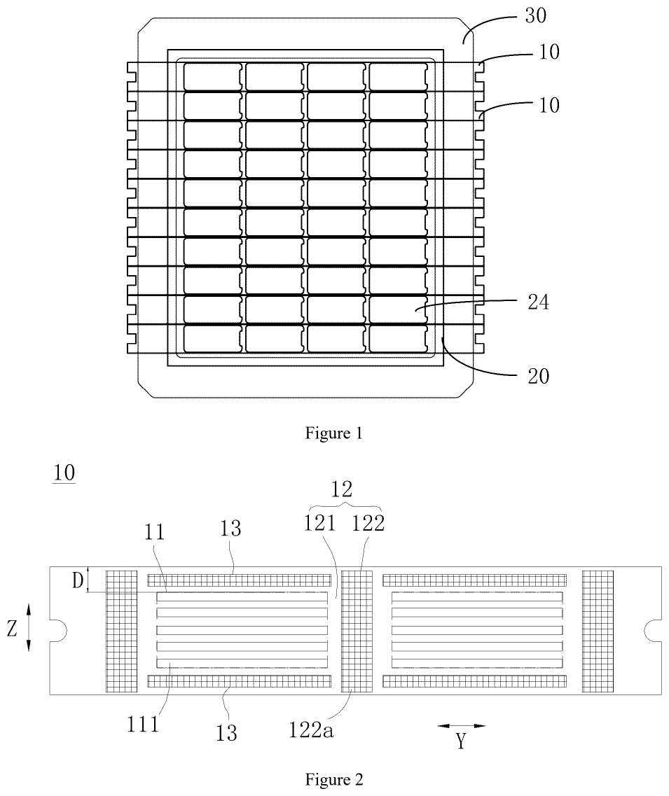

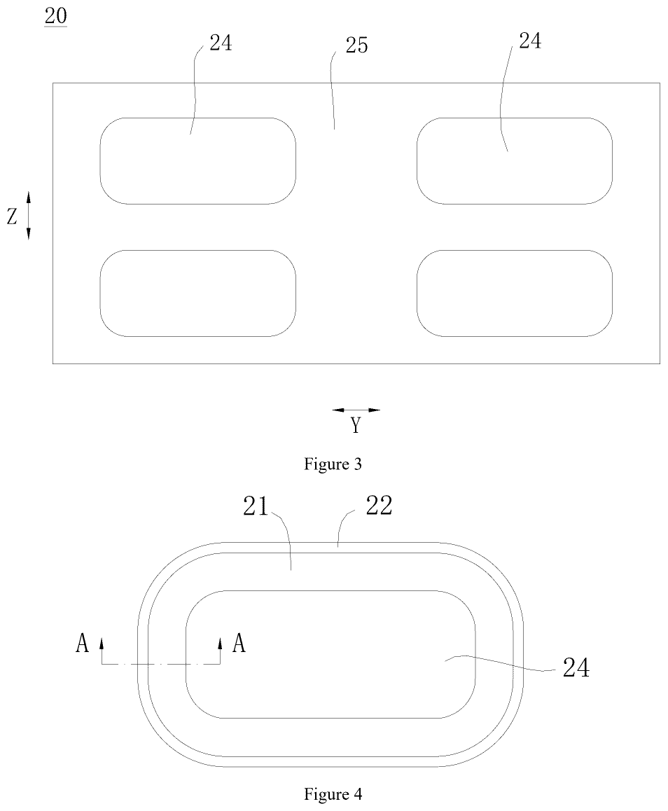

As shown in FIGS. 1 to 3, the mask device provided in the embodiments of the present application includes a first mask 10 and a second mask 20. The first mask 10 has a plurality of evaporation regions 11 and separation regions 12 between the plurality of evaporation regions 11. An evaporation openings 111 is formed in each of the evaporation regions 11. The second mask 20 is arranged on one side of the first mask 10 in a thickness direction X thereof, and the second mask 20 has a shielding portion 25 and a plurality of shaping openings 24 formed in the shielding portion 25. Each shaping opening 24 is arranged corresponding to one of the evaporation regions 11, where an orthographic projection of the shielding portion 25 covers at least part of the evaporation opening 111 in the thickness direction X.

Two, three or more evaporation regions 11 may be included in the first mask 10, and the plurality of evaporation regions 11 may be distributed at intervals on the first mask 10 in the same direction, or of course, they may be distributed in an array.

The second mask 20 and the first mask 10 may be distributed at an interval in the thickness direction X. A plurality of the shaping openings 24 may be formed in the second shielding portion 25, and each shaping opening 24 is arranged opposite one of the evaporation regions 11.

In the thickness direction X, an orthographic projection of the shielding portion 25 covers at least part of one evaporation opening 111, or of course, may cover at least part of the plurality of evaporation openings 111.

The mask device provided in the embodiments of the present application includes the first mask 10 and the second mask 20. The first mask 10 has a plurality of evaporation regions 11 and separation regions 12 located between the plurality of evaporation regions 11, and evaporation openings 111 are formed in each of the evaporation regions 11 and used to form an evaporation pattern of a corresponding shape. The second mask 20 is arranged on one side of the first mask 10 in a thickness direction X thereof, and the second mask 20 has a shielding portion 25 and a plurality of shaping openings 24 formed in the shielding portion 25. Each shaping opening 24 is arranged corresponding to one of the evaporation regions 11, and the orthographic projection of the shielding portion 25 covers at least part of the evaporation openings 111 in the thickness direction X, such that when a predetermined material is evaporated in the evaporation openings 111 of the evaporation regions 11, corresponding areas of the covered evaporation openings 111 can be shielded by the shielding portion 25. By setting the shapes of the shaping openings 24 to match the shapes of special-shaped regions, the requirements of evaporation can be met without changing the distribution or shapes of the evaporation openings 111 at the positions corresponding to the special-shaped regions, such that the probability of wrinkling of the mask device can be reduced, and the problem of the serious impact of evaporation color spots on the effect of display can be alleviated.

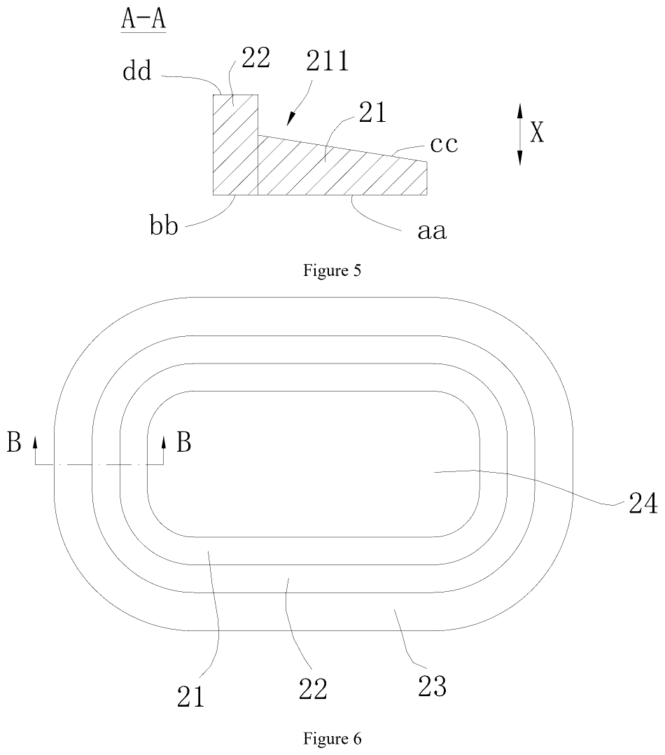

Referring to FIGS. 1 to 5 together, in some alternative embodiments, according to the mask device provided in the embodiments of the present application, the shielding portion 25 includes a first shielding ring 21 and a second shielding ring 22 that surround a shaping opening 24. The second shielding ring 22 is connected to a peripheral side of the first shielding ring 21 away from the shaping opening 24 and surrounds the first shielding ring 21. The first shielding ring 21 is provided with a buffer cutout 211 arranged facing the first mask 10 in the thickness direction X, and the first shielding ring 21 covers at least part of the evaporation opening 111.

According to the mask device provided in the embodiments of the present application, the shielding portion 25 includes the first shielding ring 21 and the second shielding ring 22 that surround the shaping opening 24, and the second shielding ring 22 is configured to facilitate fit with other components such as a glass plate, so as to ensure the position fixation and stability of the second shielding ring 22 and improve the evaporation yield of a product. Also, in the thickness direction X, the buffer cutout 211 arranged facing the first mask 10 is provided in the first shielding ring 21, and the first shielding ring 21 covers at least part of the evaporation opening 111. The buffer cutout 211 can be used to store wrinkles generated on the first mask 10, so that the number of the wrinkles of an entirety composed of the mask device is smaller, the evaporation patterns formed in corresponding regions of the shaping openings 24 are prevented from being affected by the wrinkles, and the evaporation yield is improved.

In some alternative embodiments, in the thickness direction X, an end surface aa of the first shielding ring 21 facing away from the first mask 10 is mutually flush with an end surface bb of the second shielding ring 22 facing away from the first mask 10, an end surface cc of the first shielding ring 21 facing the first mask 10 is spaced from an end surface dd of the second shielding ring 22 facing the first mask 10, and thus the buffer cutout 211 is formed.

According to the mask device provided in the embodiments of the present application, the end surface aa of the first shielding ring 21 facing away from the first mask 10 is mutually flush with the end surface bb of the second shielding ring 22 facing away from the first mask 10, on the premise of meeting the overall thickness requirement of the mask device and the depth requirement of the buffer cutout 211, an abutment area between the first shielding ring 21 and the second shielding ring 22 can be ensured, the strength of the connection between the first shielding ring 21 and the second shielding ring 22 can be increased, and thus the overall safety and stability of the mask device can be improved. In addition, with such an arrangement, when the second mask 20 is fixed at a maximum thickness value, the size of the buffer cutout 211 can be ensured to the most extent, the amount of stored wrinkles of the first mask 10 can be increased, and the evaporation yield can be ensured.

As some alternative embodiments, according to the mask device provided in the embodiments of the present application, the end surface cc of the first shielding ring 21 facing the first mask 10 is an inclined surface in the thickness direction X, and the thickness dimension of a side of the first shielding ring 21 connected to the second shielding ring 22 is greater than the thickness dimension of a side of the first shielding ring 21 facing the shaping opening 24.

According to the mask device provided in the embodiments of the present application, the end surface cc of the first shielding ring 21 facing the first mask 10 is the inclined surface, and the thickness dimension of the side of the first shielding ring 21 connected to the second shielding ring 22 is greater than the thickness dimension of the side of the first shielding ring 21 facing the shaping opening 24. With the above arrangement, when the mask device is cleaned, a chemical solution for cleaning can slip down the inclined surface, avoiding residuals of the chemical solution thereon, so that the cleaning requirements of the mask device can be met, and the problem can also be avoided that the mask device is damaged and the quality of the evaporation patterns is affected during a evaporation operation due to long-term residuals of the chemical solution.

In some alternative embodiments, according to the mask device provided in the embodiments of the present application, the thickness dimensions of the first shielding ring 21 at various portions are greater than one third of the thickness dimension of the second shielding ring 22 and less than the thickness dimension of the second shielding ring 22.

In an embodiment, the second shielding ring 22 may be an equal-thickness annular structure.

According to the mask device provided in the embodiments of the present application, the formation of the buffer cutout 211 can be facilitated and the storage of the wrinkles can be ensured by setting the thickness dimensions of the first shielding ring 21 at various portions to be greater than one third of the thickness dimension of the second shielding ring 22 and less than the thickness dimension of the second shielding ring 22. Moreover, the thickness of the first shielding ring 21 can also be appropriate to ensure that the length requirement thereof as well as the requirements of pressing and covering the first mask 10 are met.

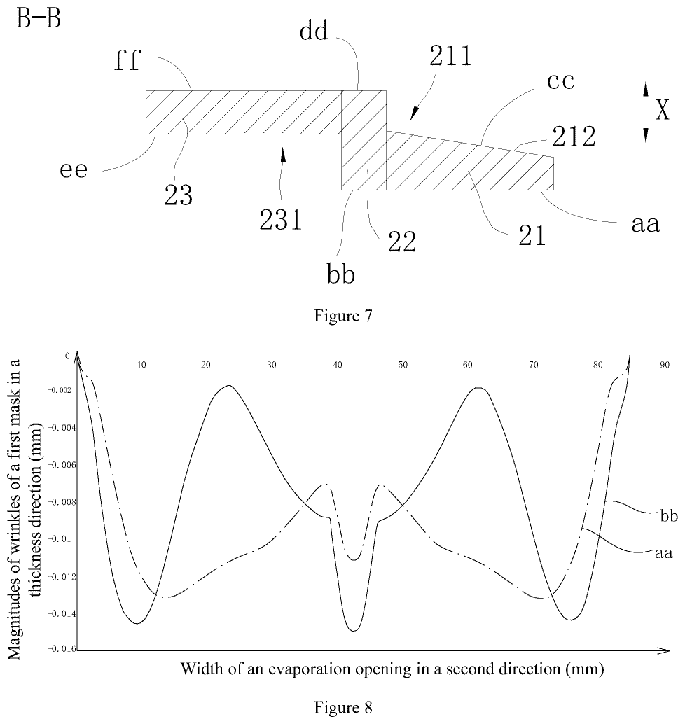

As shown in FIGS. 6 and 7, in some alternative embodiments, according to the mask device provided in the embodiments of the present application, the shielding portion 25 further includes a third shielding ring 23 surrounding the shaping opening 24, where the third shielding ring 23 is connected to a peripheral side of the second shielding ring 22 facing away from the first shielding ring 21 and surrounds the second shielding ring 22, and a weight reducing cutout 231 is provided in the third shielding ring 23.

By providing the third shielding ring 23, the area of the second shielding ring 22 fitting with other components such as the glass plate can be increased, the position fixation and stability of the second shielding ring 22 is ensured, and the evaporation yield of the product is improved.

In an embodiment, the weight reducing cutout 231 may be formed by removing the material of the third shielding ring 23, in order to reduce the weight of the third shielding ring 23. In some alternative embodiments, the weight reducing cutout 231 may include a through hole in the thickness direction X, a blind hole or groove extending in the thickness direction X, etc.

In some alternative embodiments, according to the mask device provided in the embodiments of the present application, in the thickness direction X, an end surface of a side of the third shielding ring 23 facing away from the first mask 10 is recessed toward a side where the first mask 10 is located, and forms the weight reducing cutout 231.

The weight reducing cutout 231 may be configured to be open only on the side facing away from the first mask 10, and of course, this is an alternative implementation. In some embodiments, it is also possible to configure the weight reducing cutout 231 to be open both on the side facing away from the first mask 10 and on a side facing away from the first shielding ring 21, that is to say, weight reduction can be achieved by decreasing the thickness dimension of the third shielding ring 23.

According to the mask device provided in the embodiments of the present application, the end surface of the side of the third shielding ring 23 facing away from the first mask 10 is recessed toward the side where the first mask 10 is located, and forms the weight reducing cutout 231, so that the requirement of weight reduction can be achieved and the area of the third shielding ring 23 fitting with structures such as the glass plate can be effectively ensured, improving the overall stability of the mask device.

In some alternative embodiments, according to the mask device provided in the embodiments of the present application, in the thickness direction X, an end surface ff of the third shielding ring 23 facing the first mask 10 is mutually flush with the end surface dd of the second shielding ring 22 facing the first mask 10, and an end surface ee of the third shielding ring 23 facing away from the first mask 10 has a height difference from the end surface bb of the second shielding ring 22 facing away from the first mask 10.

That is to say, the thickness of the third shielding ring 23 is less than the thickness of the second shielding ring 22 in the thickness direction X.

According to the mask device provided in the embodiments of the present application, in the thickness direction X, the end surface ff of the third shielding ring 23 facing the first mask 10 is mutually flush with the end surface dd of the second shielding ring 22 facing the first mask 10, so that when the mask device is used, the second shielding ring 22 and the third shielding ring 23 can both abut against the structures such as the glass plate, and insufficient contact areas between the rings and the glass plate due to the height difference therebetween can be avoided. Furthermore, with the above arrangement, on the premise of meeting the total thickness requirement of the mask device and the depth requirement of the weight reducing cutout 231, the abutment area between the second shielding ring 22 and the third shielding ring 23 can be secured, the strength of the connection between the second shielding ring 22 and the third shielding ring 23 can be increased, and thus the overall safety and stability of the mask device can be improved.

In some alternative embodiments, according to the mask device provided in the embodiments of the present application, the thickness dimension of the third shielding ring 23 is less than two thirds of the thickness dimension of the second shielding ring 22 in the thickness direction X.

According to the mask device provided in the embodiments of the present application, the thickness dimension of the third shielding ring 23 is less than two thirds of the thickness dimension of the second shielding ring 22 in the thickness direction X, such that the stability performance of the mask device during operation can be improved, the weight requirement of the mask device can also be met, the usage rate of the material can be lowered, and the costs can be reduced.

In some alternative embodiments, according to the mask device provided in the embodiments of the present application, the third shielding ring 23 may be an equal-thickness annular structure in the thickness direction X, such that the requirement of weight reduction can be met and processing is also facilitated.

Still referring to FIGS. 1 to 7, as some alternative embodiments, according to the mask device provided in the embodiments of the present application, the separation region 12 includes an equal-thickness portion 121 and a stress removal portion 122, where the equal-thickness portion 121 is arranged close to the shaping opening 24, and a first gap 122a is provided in the stress removal portion 122.

According to the mask device provided in the embodiments of the present application, the separation region 12 is provided in such a way that two adjacent evaporation regions 11 can be disconnected from each other by using a separation region 12, and the risk can be avoided that the arrangement of the evaporation openings 111 causes wire entanglement between the two adjacent evaporation regions 11 during cleaning. Moreover, the separation region 12 to include the equal-thickness portion 121 and the stress removal portion 122 such that a phenomenon such as deformation, which is caused by a large strength difference between the evaporation regions 11 and the separation region 12, is prevented, and a stress can be released by the stress removal portion 122, such that the safety performance of the mask device during use and cleaning is improved.

As some alternative embodiments, in the mask device provided in the embodiments of the present application, a plurality of first gaps 122a are provided, the plurality of first gaps 122a are arranged spaced from each other, and entirety of the stress removal portion 122 is of a mesh structure. With the above arrangement, the strength difference between the evaporation regions 11 and the separation region 12 can be decreased, and strength regions of the stress removal portion 122 at various positions can also be consistent, such that the uniformity of bearing capacity is ensured and the probabilities of wire entanglement and deformation are reduced.

In some alternative embodiments, according to the mask device provided in the embodiments of the present application, the equal-thickness portion 121 may be of a solid plate-like structure, which can separate two adjacent evaporation regions 11 and provide sufficient support to the evaporation regions 11, so that the phenomenon of the deformation or internal wire entanglement thereof is avoided.

In some alternative embodiments, according to the mask device provided in the embodiments of the present application, the first mask 10 further has reinforcement regions 13, the evaporation regions 11 are arranged spaced from edges of the first mask 10, and the reinforcement regions 13 are formed between the evaporation regions 11 and the edges of the first mask 10.

By providing the reinforcing regions 13, the strength of the evaporation region 11 close to an edge region of the first mask 10 can be ensured, the risk of wire entanglement between two adjacent first masks 10 is avoided, and the safety performance is improved.

In some alternative embodiments, a minimum separation distance D between the evaporation region 11 and the edge of the first mask 10 is any value ranging from 0.5 mm to 1 mm, including two end values of 0.5 mm and 1 mm, In an embodiment any value ranging from 0.6 mm to 0.9 mm, and may be 0.7 mm, 0.8 mm, etc. as an example.

In the mask device provided in the embodiments of the present application, the minimum separation distance between the evaporation region 11 and the edge of the first mask 10 is any value ranging from 0.5 mm to 1 mm, such that a space can be reserved for the reinforcement region 13, which is conducive to arranging the reinforcement region 13 and effectively reducing the risk of wire entanglement between two adjacent second masks 20.

In some alternative embodiments, according to the mask device provided in the above embodiments of the present application, a plurality of evaporation openings 111 are formed in each evaporation region 11, the evaporation openings 111 are stripe-shaped holes extending in a first direction Y, and the plurality of evaporation openings 111 in the same evaporation region 11 are distributed at intervals in a second direction Z, where the first direction Y intersects with the second direction Z.

With the above arrangement, the mask device provided in the embodiments of the present application can meet the requirements for evaporation patterns. Also, with the above configuration, the opening size of the mask device can be increased, and thus the opening rate of a display panel formed by evaporation using the mask device as a shield is ensured.

And, with the above configuration, the mask device is suitable for the form that first sub-pixels and second sub-pixels are in the same column or row and third sub-pixels are in a separate column or row. The first sub-pixels, the second sub-pixels and the third sub-pixels may be red sub-pixels, green sub-pixels and blue sub-pixels. When the third sub-pixels are the blue sub-pixels, for the formed display panel, the effect of colored edges can be reduced while a pixel opening rate is increased.

In some alternative embodiments, according to the mask device provided in the embodiments of the present application, the evaporation openings 111 have the same length dimension in the first direction Y.

According to the mask device provided in the embodiments of the present application, the evaporation openings 111 have the same length dimension in the first direction Y.

As shown in FIG. 8, aa represents a curve of magnitudes of the wrinkles of the first mask in a thickness direction with the same length dimension of the evaporation openings 111 in the first direction. bb represents a curve of magnitudes of the wrinkles of the first mask in the thickness direction with different length dimensions of the evaporation openings 111 in the first direction. After simulation analysis, compared with the curve aa, that is, the situation where the evaporation openings 111 have the same length dimension in the first direction Y, the simulation result curve bb with different length dimensions of the evaporation openings 111 in the first direction Y shows increased wave peaks and wave troughs, and that the floating values of the wave peaks and the wave troughs are larger, which is not conducive to evaporation fit. However, in the mask device provided in the embodiments of the present application, the simulation result curve aa shows less wave peaks and wave troughs, and that the floating values of the wave peaks and the wave troughs are smaller, which is conducive to evaporation fit.

In some alternative embodiments, according to the mask device provided in the embodiments of the present application, the shielding portion 25 covers an end of the evaporation opening 111 in the first direction Y. With the above arrangement, the amount of stored wrinkles can be ensured, such that the entire mask device has smaller wrinkles, the effect of the mask device better fitting with the glass plate is ensured, and the evaporation yield is increased.

It should be understood that the evaporation openings 111 are stripe-shaped holes extending in the first direction Y, the plurality of evaporation openings 111 in the same evaporation region 11 are distributed at intervals in the second direction Z, and the first direction Y intersecting with the second direction Z is merely an alternative implementation, and is not limited to the above configuration.

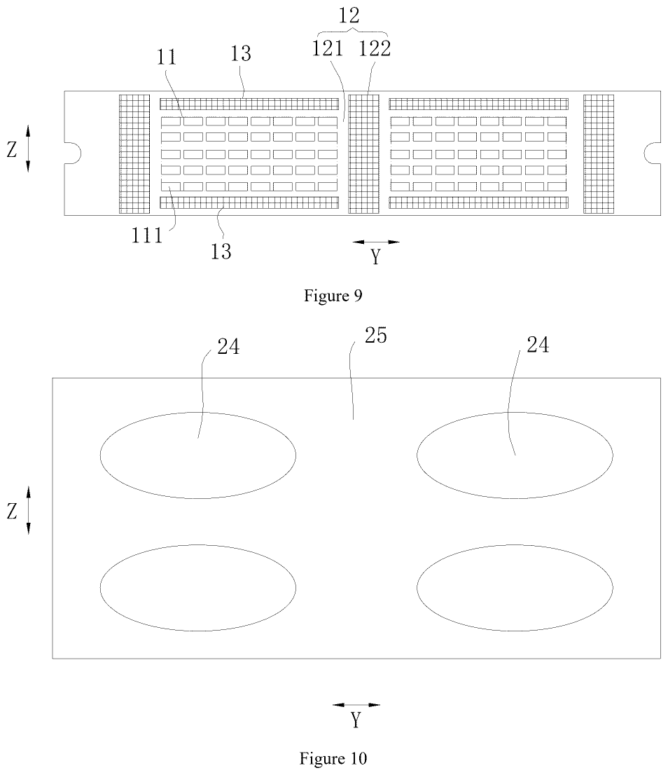

As shown in FIG. 9, in some embodiments, according to the mask device provided by the present application, a plurality of evaporation openings 111 are provided in each evaporation region 11, the evaporation openings 111 are in the form of one of circular, elliptic and polygonal shapes, more than two evaporation openings 111 are distributed at intervals in the first direction Y in the same evaporation region 11, and more than two evaporation openings 111 are distributed at intervals in the second direction Z, where the first direction Y intersects with the second direction Z.

With the above arrangement, the evaporation openings can also cooperate with the second mask 20 to meet the evaporation requirements, and the problem that the evaporation color spots seriously affect the effect of display can be alleviated.

In some alternative embodiments, according to the mask device provided in the embodiments of the present application, an orthographic projection of the shaping opening 24 is in the form of one of a circle, an ellipse, a kidney, a water drop, and a polygon with an apex angle in circular arc transition, in the thickness direction X.

As an example, as shown in FIGS. 2 to 5, an orthographic projection of the shaping opening 24 may be in the kidney shape. Of course, this is an alternative embodiment. In some embodiments, as shown in FIG. 10, the orthographic projection of the shaping opening 24 may also be in the elliptic shape.

The shaping openings 24 are in the above-mentioned shapes such that requirements for different display shapes of the display panel can be met and the versatility of the mask device is improved.

Still referring to FIG. 1, in some alternative embodiments, the mask device provided in the embodiments of the present application further includes a mask frame 30, and the first mask 10 and the second mask 20 are each connected to the mask frame 30.

According to the mask device provided in the embodiments of the present application, the mask frame 30 is provided and a connection relationship between the first mask 10, the second mask 20 and the mask frame 30 is defined, such that the relative position fixation of the first mask 10 and the second mask 20 can be ensured, the alignment of the first mask 10 and the second mask 20 with the regions 11 for evaporation is also facilitated, and the evaporation requirements for the display panel can be met.

In an embodiment, the mask frame 30 may be of a hollow polygonal frame structure, and a rectangular frame structure as an example.

In an embodiment, each second mask 20 may correspond to one first mask 10. Of course, each second mask 20 may also correspond to more than two first masks 10.

In an embodiment, the first mask 10 and the second mask 20 may be connected to the mask frame 30 by soldering or other methods to meet the requirement of the strength of the connection between the masks and the mask frame 30.

In some alternative embodiments, according to the mask device provided in the embodiments of the present application, the orthographic projection area of the second mask 20 is greater than the orthographic projection area of the first mask 10 in the thickness direction X, a plurality of first masks 10 are provided, and the plurality of first masks 10 are spliced successively and each connected to the mask frame 30.

In an embodiment, each second mask 20 may correspond to two or more first masks 10.

According to the mask device provided in the embodiments of the present application, the plurality of first masks 10 are provided, and when the structure of the second mask 20 is larger, the plurality of first masks 10 can be separately processed and then spliced, so that the overall processing difficulty of the mask device is reduced, the processing precision of the evaporation openings 111 in each evaporation region 11 can be ensured, and the evaporation yield is be increased.

In some alternative embodiments, according to the mask device provided in the embodiments of the present application, the first mask 10 may be of a strip-shaped structure, and more than two first masks 10 may be arranged successively in the same direction and spliced with each other. This is conducive to processing and can reduce the size of joints.

As some alternative embodiments, according to the mask device provided by the present application, the first mask 10, the second mask 20 and the mask frame 30 may be connected by means of soldering. Of course, the connection may also be achieved by means of securing with fasteners, as long as fixed relative positions of the three components can be ensured.

Although the present application is described with reference to the embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific embodiments disclosed herein but includes all the embodiments that fall within the scope of the claims.

1. A mask device, wherein comprising:
a first mask, having a plurality of evaporation regions and a plurality of separation regions located between the plurality of evaporation regions, each of the evaporation regions having at least one evaporation opening defined therein; and
a second mask, arranged on one side of the first mask in a thickness direction of the first mask, the second mask having a shielding portion and a plurality of shaping openings formed in the shielding portion, each of the shaping openings being arranged corresponding to one of the evaporation regions;
wherein the at least one evaporation opening comprises a plurality of evaporation openings, an orthographic projection of the shielding portion covers at least some of the evaporation openings in the thickness direction.

2. The mask device according to claim 1, wherein the shielding portion comprises a first shielding ring and a second shielding ring that surround the shaping opening, wherein the second shielding ring is connected to a peripheral side of the first shielding ring facing away from the shaping opening and surrounds the first shielding ring; and
the first shielding ring has a buffer cutout arranged facing the first mask in the thickness direction, and the first shielding ring covers at least part of the evaporation opening.

3. The mask device according to claim 2, wherein in the thickness direction, an end surface of the first shielding ring facing away from the first mask is flush with an end surface of the second shielding ring facing away from the first mask, an end surface of the first shielding ring facing the first mask is spaced from an end surface of the second shielding ring facing the first mask, to form the buffer cutout therebetween.

4. The mask device according to claim 2, wherein in the thickness direction, an end surface of the first shielding ring facing the first mask is an inclined surface, and a thickness dimension of a side of the first shielding ring connected to the second shielding ring is greater than a thickness dimension of a side of the first shielding ring facing the shaping opening.

5. The mask device according to claim 2, wherein the thickness dimensions of the first shielding ring at various portions are greater than one third of the thickness dimension of the second shielding ring and less than the thickness dimension of the second shielding ring.

6. The mask device according to claim 2, wherein the shielding portion further includes a third shielding ring surrounding the shaping opening, the third shielding ring being connected to a peripheral side of the second shielding ring facing away from the first shielding ring and surrounding the second shielding ring, and the third shielding ring having a weight reducing cutout defined therein.

7. The mask device according to claim 6, wherein in the thickness direction, an end surface of a side of the third shielding ring facing away from the first mask is recessed toward a side where the first mask is located, to form the weight reducing cutout.

8. The mask device according to claim 6, wherein in the thickness direction, the end surface of the third shielding ring facing the first mask is flush with an end surface of the second shielding ring facing the first mask, and an end surface of the third shielding ring facing away from the first mask has a height difference from an end surface of the second shielding ring facing away from the first mask.

9. The mask device according to claim 6, wherein in the thickness direction, the thickness dimension of the third shielding ring is greater than one third of the thickness dimension of the second shielding ring, and less than two thirds of the thickness dimension of the second shielding ring.

10. The mask device according to claim 1, wherein the separation region comprises an equal-thickness portion and a stress removal portion, the equal-thickness portion being arranged close to the shaping opening, and the stress removal portion having a first gap provided therein.

11. The mask device according to claim 1, wherein the first mask further has a reinforcement region, the evaporation regions are arranged spaced from edges of the first mask, and the reinforcement region is formed between the evaporation region and the edge of the first mask.

12. The mask device according to claim 11, wherein a minimum separation distance between the evaporation regions and the edges of the first mask ranges from 0.5 mm to 1 mm.

13. The mask device according to claim 1, wherein a plurality of evaporation openings are formed in each evaporation region, the evaporation openings are stripe-shaped holes extending in a first direction, and the plurality of evaporation openings in the same evaporation region are distributed at intervals in a second direction, the first direction intersecting with the second direction.

14. The mask device according to claim 13, wherein the evaporation openings have the same length dimension in the first direction.

15. The mask device according to claim 13, wherein the shielding portion covers ends of the evaporation openings in the first direction.

16. The mask device according to claim 13, wherein each of the evaporation openings is in the form of one of circular, elliptic and polygonal shapes, and in the same evaporation region, more than two evaporation openings are distributed at intervals in the first direction, and more than two evaporation openings are distributed at intervals in the second direction, the first direction intersecting with the second direction.

17. The mask device according to claim 1, wherein in the thickness direction, an orthographic projection of the shaping opening is in the form of one of a circle, an ellipse, a kidney, a water drop, and a polygon with an apex angle in circular arc transition.

18. The mask device according to claim 1, wherein the mask device further comprises a mask frame, and the first mask and the second mask are respectively connected to the mask frame.

19. The mask device according to claim 18, wherein the orthographic projection area of the second mask is greater than the orthographic projection area of the first mask in the thickness direction, a plurality of first masks are provided, and the plurality of first masks are spliced in sequence and respectively connected to the mask frame.
